(19) United States
(12) Patent Application Publication
(10) Pub. No.: US 2026/0341394 A1
(43) Pub. Date: Oct. 29, 2026

(54) APPARATUSES AND METHODS FOR REFRESH ADDRESS MASKING

(71) Applicant: Micron Technology, Inc., Boise, ID (US)

(72) Inventors: Yoshinori Fujiwara, Boise, ID (US); Michael A. Shore, Boise, ID (US); Kevin G. Werhane, Kuna, ID (US); Robert Briggs, Boise, ID (US); John E. Riley, McKinney, TX (US); Scott E. Smith, Plano, TX (US); Christian N. Mohr, Allen, TX (US)

(73) Assignee: Micron Technology, Inc., Boise, ID (US)

(21) Appl. No.: 19/634,708

(22) Filed: Mar. 31, 2026

Related U.S. Application Data
(60) Provisional application No. 63/796,855, filed on Apr. 29, 2025.

(51) Int. Cl. G11C 29/00

(52) U.S. Cl. CPC G11C 29/783; G11C 29/76

(57) ABSTRACT

Apparatuses, systems, and methods for refresh address masking. A memory device may refresh word lines as part of refresh operation by cycling through the word lines in a sequence. However, it may be desirable to avoid activating certain word lines (e.g., because they are defective). Refresh masking circuits may utilize redundancy circuitry which stores addresses associated with word lines that have been repaired. When a refresh address is generated for a certain region of the memory array, it may be compared to the stored address. If there is a match, a refresh stop signal may be activated, which may prevent refreshing of the word line(s).

### CROSS REFERENCE TO RELATED APPLICATIONS

This application claims the benefit under 35 U.S.C. § 119 of the earlier filing date of U.S. Provisional Application Serial No. 63/796,855 filed Apr. 28, 2026. The aforementioned application is incorporated herein by reference, in its entirety, for any purpose.

### BACKGROUND

This disclosure relates generally to memory devices, and more specifically to semiconductor memory devices. In particular, the disclosure relates to volatile memory, such as dynamic random access memory (DRAM). Information may be stored on individual memory cells of the memory as a physical signal (e.g., a charge on a capacitive element). The memory may be a volatile memory, and the physical signal may decay over time (which may degrade or destroy the information stored in the memory cells). It may be necessary to periodically refresh the information in the memory cells by, for example, rewriting the information to restore the physical signal to an initial value.

The memory may also carry out repair operations, where defective memory cells are disabled. For example, an address previously associated with a defective word line may be reassigned to a redundant word line and the defective word line may be disabled for access operations. There may be circumstances where the defective word line is still refreshed as part of a refresh cycle of the memory. However, some defective word lines may create instability in the array if activated by refresh operations. Accordingly, preventing refreshes of some defective word lines may be desirable.

### BRIEF DESCRIPTION OF THE DRAWINGS

FIG. 1 is a block diagram of a memory device according at least one embodiment of the disclosure.

FIG. 2 is a block diagram of at least a portion of a memory device according to at least one embodiment of the disclosure.

FIG. 3 is a block diagram of at least a portion of a memory device according to at least one embodiment of the disclosure.

FIG. 4 is a block diagram of at least a portion of a memory device according to at least one embodiment of the disclosure.

FIG. 5 is a flow chart of a method according to at least one embodiment of the disclosure.

### DETAILED DESCRIPTION

The following description of certain embodiments is merely exemplary in nature and is in no way intended to limit the scope of the disclosure or its applications or uses. In the following detailed description of embodiments of the present apparatuses, systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed apparatuses, systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a volatile memory device may be stored in memory cells (e.g., as a charge on a capacitive element), and may decay over time. The memory cells may be organized into rows (word lines) and columns (bit lines), in each bank of a memory array. In order to prevent information from being lost or corrupted due to this decay, the memory may carry out a background refresh process, such as auto-refresh or self-refresh operations. The memory cells may be refreshed on a row-by-row basis. During a refresh operation, information may be rewritten to the word line to restore its initial state. The memory may perform a refresh cycle by performing refresh operations on the word lines of the memory in a sequence such that over time the word lines of the memory are refreshed at a rate faster than the expected rate of data degradation.

A memory array may include one or more memory cells which are defective (e.g., due to manufacturing defects). These defective memory cells may be identified, and repair operations may be performed to enable redundant memory cells in the place of the defective memory cells. The repair may not physically change the defective memory cells. Rather, the addresses that are mapped or assigned to defective memory cells can be remapped to non-defective memory cells (i.e., functional) so that the memory device can still be effective. In other words, the repair swaps out the defective memory cells for non-defective memory cells.

For example, a memory array may generally include a number of additional rows of memory, which may generally be referred to as redundant memory. During a repair operation, a row address associated with a defective row may be redirected or remapped so that the row address is associated with one of the redundant rows instead. The remapped addresses may be stored in non-volatile storage in the memory device. For example, the memory device may include one or more fuse arrays that can include fuses (and/or anti-fuses) which may have state that can be permanently changed (e.g., when the fuse/anti-fuse is “blown”). The state of the fuses/anti-fuses in the fuse bank may, in part, determine which addresses are associated with which rows of memory.

Each fuse may be in a first state where it is conductive until the fuse is ‘blown’ to make the fuse insulating instead. Each anti-fuse may be in a first state which is non-conductive until the anti-fuse is blown to make the anti-fuse conductive instead. Each fuse/anti-fuse may permanently change when it is blown. Each fuse/anti-fuse may be considered to be a bit, which is in one state before it is blown, and permanently in a second state after it's blown. For example, a fuse may represent a logical low before it is blown and a logical high after it is blown, while an anti-fuse may represent a logical high before it is blown and a logical low after it is blown. It should be understood that discussions of fuses as used herein may generally refer to either fuses or anti-fuses and that embodiments may use fuses, anti-fuses, or a combination thereof.

In a conventional memory device, during a refresh cycle, the defective word lines may be refreshed, even if they have already been repaired. This may present problems based on the type of defect in the defective word line. In some situations, certain defective word lines may operate outside of the device’s specification (e.g., may take too long to turn off), which in turn may cause errors or even damage to the memory device if the row is refreshed. However, it may take time to determine if a given refresh address is associated with any of the defective word lines, which may unacceptably increase the time required for refresh operations.

U.S. Patent 11,670,356, which is incorporated herein by reference for any purpose, describes a refresh masking circuit for a memory bank that compares a current CBR address to a relatively small number of selected addresses. However, in some instances there may be many defective rows that should not be refreshed. In some instances, the defective rows may be located physically near each other in the memory bank. This may be due to a processing and/or material defect in the die in some cases. Thus, in some applications, it may be desirable to mask off larger portions (e.g., more than two main word lines) of the memory array to prevent refreshing of defective rows.

The present disclosure is drawn to apparatuses, systems, and methods for refresh address masking. The memory may have refresh masking circuitry that includes one or more circuits. The refresh masking circuitry may be programmed with a region code (e.g., by programming fuses/anti-fuses) that indicates a region or regions of the memory array. For example, the region code may indicate a quadrant of a memory bank. The region may represent an area that includes defective word lines that are undesirable to refresh. Defective word lines may have been identified during a testing operation.

A refresh counter (e.g., a CAS-before-RAS or CBR counter) may generate a refresh address (e.g., CBR address) for automatic refresh operations. For certain regions of the memory array, the refresh masking circuitry may activate redundancy check circuitry that is typically deactivated during automatic refresh operations. The redundancy check circuitry may compare that CBR address to the addresses of repaired rows stored in the fuse array. If there is a match, the refresh masking circuit may provide a refresh masking signal which may prevent the word line(s) associated with that CBR address from being refreshed.

In some embodiments, the CBR address may be compressed compared to a row address meaning the CBR address has fewer bits than a row address. The compression may cause the CBR address to be associated with multiple word lines. For example, a portion of the CBR address may be truncated (compared to a normal row address), and the CBR address may be associated with every word line which shares the remaining bits of the CBR address in common. For example, if two bits are truncated from the CBR address, it may be associated with four word lines; if three bits are truncated then it may be associated with eight word lines, etc. In some embodiments, all of the word lines associated with the CBR address which matches the selected address may be skipped.

As used herein, compressed or truncated may refer to addresses in which some bits which are normally used as part of that address are missing/ignored. For example, if a normal row address is 16 bits, and two bits are ignored or omitted from an address signal, then the compressed or truncated address may have 14 bits. While certain examples may be given in terms of number of bits truncated, or which bits of an address are truncated, it should be understood that these may vary in other embodiments.

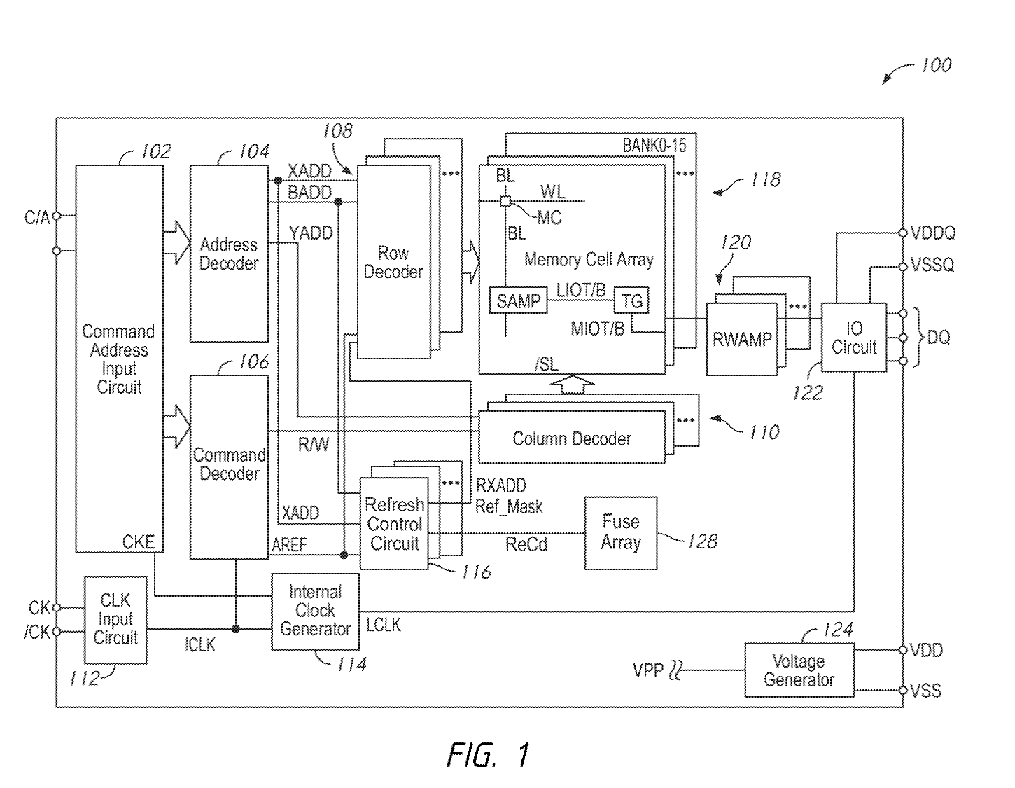

FIG. 1 is a block diagram of a memory device according at least one embodiment of the disclosure. The memory device 100 may be a semiconductor memory device, such as a DRAM device integrated on a single semiconductor chip.

The memory device 100 includes a memory array 118. The memory array 118 is shown as including a plurality of memory banks. In the embodiment of FIG. 1, the memory array 118 is shown as including sixteen memory banks BANK0-BANK15. More or fewer banks may be included in the memory array 118 of other embodiments. Each memory bank includes a plurality of word lines WL, a plurality of bit lines BL and /BL, and a plurality of memory cells MC arranged at intersections of the plurality of word lines WL and the plurality of bit lines BL and /BL. The selection of the word line WL is performed by a row decoder 108 and the selection of the bit lines BL and /BL is performed by a column decoder 110. In the embodiment of FIG. 1, the row decoder 108 includes a respective row decoder for each memory bank and the column decoder 110 includes a respective column decoder for each memory bank. The bit lines BL and /BL are coupled to a respective sense amplifier (SAMP). Read data from the bit line BL or /BL is amplified by the sense amplifier SAMP, and transferred to read/write amplifiers 120 over complementary local data lines (LIOT/B), transfer gate (TG), and complementary main data lines (MIOT/B). Conversely, write data outputted from the read/write amplifiers 120 is transferred to the sense amplifier SAMP over the complementary main data lines MIOT/B, the transfer gate TG, and the complementary local data lines LIOT/B, and written in the memory cell MC coupled to the bit line BL or /BL.

The memory device 100 may employ a plurality of external terminals that include command and address (C/A) terminals coupled to a command and address bus to receive commands and addresses, and a CS signal, clock terminals to receive clocks CK and /CK, data terminals DQ to provide data, and power supply terminals to receive power supply potentials VDD, VSS, VDDQ, and VSSQ.

The clock terminals are supplied with external clocks CK and /CK that are provided to an input circuit 112. The external clocks may be complementary. The input circuit 112 generates an internal clock ICLK based on the CK and /CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The device 100 may receive an access command which is a read command. When a read command is received, and a bank address, a row address and a column address are timely supplied with the read command, read data is read from memory cells in the memory array 118 corresponding to the row address and column address. The read command is received by the command decoder 106, which provides internal commands so that read data from the memory array 118 is provided to the read/write amplifiers 120. The read data is output to outside from the data terminals DQ via the input/output circuit 122.

The device 100 may receive an access command which is a write command. When the write command is received, and a bank address, a row address and a column address are timely supplied with the write command, write data supplied to the data terminals DQ is written to a memory cells in the memory array 118 corresponding to the row address and column address. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC.

The device 100 may also receive commands causing it to carry out one or more refresh operations as part of a refresh mode. In some embodiments, the refresh mode command may be externally issued to the memory device 100. In some embodiments, the refresh mode command may be periodically generated by a component of the device. In some embodiments, when an external signal indicates a refresh entry command, the refresh signal AREF may also be activated. The refresh signal AREF may be used to control the timing of refresh operations during the refresh mode. The signal AREF may be generated with periodic timing during the refresh mode. Thus, refresh operations may continue automatically. A refresh mode exit command (which may be from an external controller and/or may be internally generated) may cause the periodic activation of the refresh signal AREF to stop and may cause the device 100 to return to an idle state and/or resume other operations.

The refresh signal AREF is supplied to a refresh control circuit 116. In some embodiments, such as the one shown in FIG. 1, a refresh control circuit 116 may be provided for each memory bank. The refresh control circuit 116 supplies a refresh row address RXADD to the row decoder 108, which may refresh one or more word lines WL indicated by the refresh row address RXADD. In some embodiments, the refresh address RXADD may represent a single word line. In some embodiments, the refresh address RXADD may represent multiple word lines, which may be refreshed sequentially or simultaneously by the row decoder 108. For example, the refresh address RXADD may be truncated compared to the row address XADD, and the refresh address RXADD may be associated with every word line which shares the non-truncated portion of the address in common. The refresh control circuit 116 may control a timing of the refresh operation and may generate and provide the refresh address RXADD. The refresh control circuit 116 may be controlled to change details of the refreshing address RXADD (e.g., how the refresh address is calculated, the timing of the refresh addresses, the number of word lines represented by the address), or may operate based on internal logic.

The refresh control circuit 116 may selectively output a targeted refresh address which specifies one or more victim address based on an identified aggressor word line or an automatic refresh address (e.g. a CAS before RAS or CBR address) which is part of a sequence of addresses as the refresh address RXADD. Based on the type of refresh address RXADD (and in some embodiments, one more additional signals indicating the type of operation), the row decoder 108 may perform a targeted refresh or CBR refresh operation. The automatic refresh addresses may be generated as part of a sequence of addresses which are intended to refresh all of the word lines in the memory array 118. The refresh control circuit 116 may cycle through the sequence of refresh addresses at a rate determined by AREF. The auto-refresh operations may generally occur with a timing such that the sequence of CBR addresses is cycled such that no information is expected to degrade in the time between refresh operations for a given word line. In other words, refresh operations may be performed such that each word line is refreshed at a rate faster than the expected rate of information decay.

The memory array may include one or more word lines which are defective (e.g., due to manufacturing defects). These word lines may be disabled, and the row address previously associated with the defective word lines may be repaired by reassigning the addresses to redundant word lines of the memory array 118. A fuse array 128 may be programmed to remap the addresses to redundant rows. Although not shown, the row decoder 108 and/or bank logic may include redundancy check circuitry that receive information from the fuse array 128. During access operations (e.g., read, write), the row address XADD associated with the access command may be checked against the redundancy information in the fuse array 128. If the received row address XADD matches a repaired address in the fuse array 128, the appropriate redundant row is accessed instead of the defective row.

Even though the defective rows are no longer activated during access operations, the defective rows may be activated during refresh operations and refreshed. Most of the defective word lines in a memory array may not be sufficiently damaged to represent problems if activated and may be refreshed as normal (although the refreshing may serve no practical purpose if the word line is disabled as part of a repair operation). In situations where the defect in the word lines may disrupt operations in the memory device 100 or even cause damage to the memory device 100 or information stored therein if refreshed, the word lines may be masked off. In many cases, the defective word lines are not randomly distributed across the memory array 118. Rather, all or a majority of defective word lines may be clustered in a same physical region of the array. Accordingly, ensuring defective word lines are not refreshed may be more important for some regions of the memory array 118 than others.

According to embodiments of the present disclosure, the fuse array 128 may include fuses programmed with one or more regions of the memory array 118 which indicate selected region(s) in which defective rows which should not be refreshed. The defective word lines in the selected region(s) may represent defective word lines which if activated would operate outside of the device’s specification. All repaired word lines in the selected region(s) in all of the banks may be masked (e.g., not refreshed). Repaired word lines in non-selected regions may be refreshed in some embodiments.

The selected region(s) may be identified during testing. For example, the time it takes word line to close may be measured, and the defective word lines may be word lines which have a closing time which exceeds a threshold. If many word lines are in a same region of the memory array, that region may be selected. In addition to being identified as defective, the word lines may also be identified as associated with a defective address and may be repaired by remapping the address to a redundant word line for access purposes. Typically, refresh operations may bypass the redundancy circuitry which would identify the defective word lines as repaired, and thus those defective word lines may normally be refreshed. However, according to embodiments of the present disclosure, when the address is associated with the selected region(s), the redundancy circuitry is activated to identify the defective word lines in the region and prevent the defective word lines from being refreshed.

In some embodiments, the selected region(s) may be stored as region codes ReCd in the fuse array 128 (e.g., by blowing one or more fuses). In some embodiments, different region codes ReCd may be programmed for each bank of the memory array 118. In some embodiments, an additional fuse may be included that is programmed to enable or disable region-based masking. In some embodiments, the refresh control circuit 116 may include fuse latches that receive the region codes ReCd from the fuse array 128 during a broadcast operation. The fuse latches may store bits corresponding to the region codes ReCd. During refresh operations, if a CBR address is for a selected region (based on the programmed region code), the refresh control circuit 116 may activate redundancy control circuitry to compare the CBR address to the selected address. If a match is found by the redundancy control circuitry, the refresh control circuit 116 may provide a refresh masking signal Ref_Mask at an active level. Responsive to the refresh masking signal at the active level, the row decoder 108 may mask the refresh address RXADD and will not refresh the word line(s) associated with the refresh address. This may prevent activation of the defective word line associated with the CBR address during refresh operations. If the refresh masking signal is inactive, the refresh address RXADD may be passed and the word line(s) associated with RXADD will be refreshed.

While FIG. 1 shows a refresh control circuit 116 for each memory bank, in some embodiments, at least some of the refresh control circuitry may be shared by the refresh control circuits 116. For example, the CBR counter that generates the auto refresh addresses (CBR addresses) may be shared by all of the memory banks. Similarly, while one fuse array 128 is shown in FIG. 1, there may be multiple fuse arrays 128 in some embodiments. Further, while the refresh control circuits 116 and fuse array 128 are shown in a central peripheral region, some or all of the components of the refresh control circuits 116 and/or fuse array 128 may be located in or near bank logic region(s) for the memory banks.

The power supply terminals are supplied with power supply potentials VDD and VSS. The power supply potentials VDD and VSS are supplied to an internal voltage generator circuit 124. The internal voltage generator circuit 124 generates various internal potentials VPP and other internal voltages based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

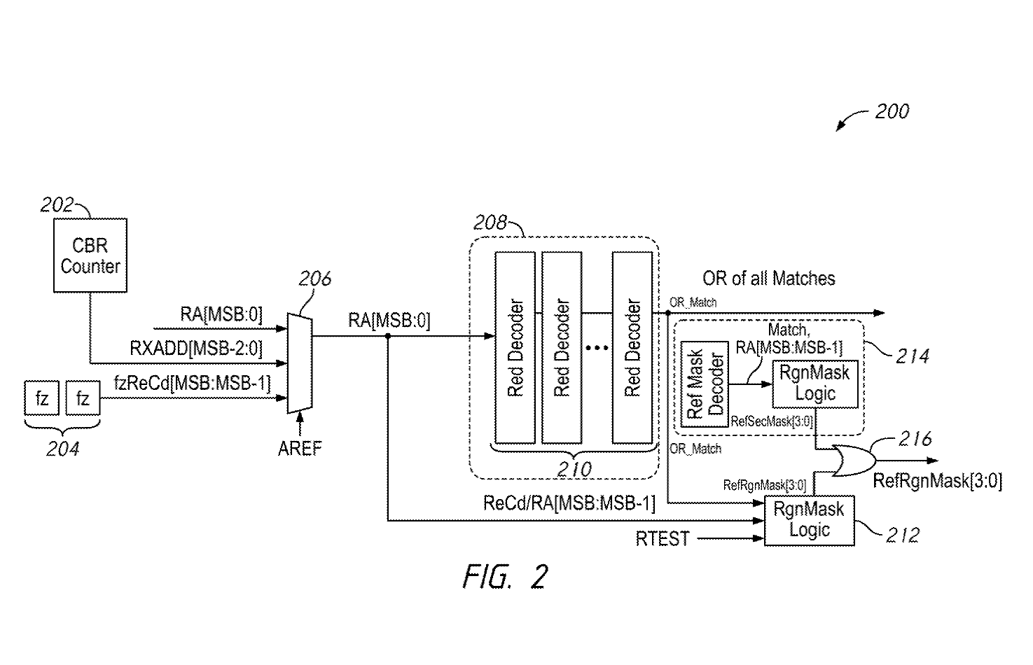

FIG. 2 is a block diagram of at least a portion of a memory device according to at least one embodiment of the disclosure. The memory device 200 may be included in memory device 100 in some embodiments. The memory device 200 may include a CBR counter 202, fuse latches 204, multiplexer (MUX) 206, redundancy circuitry 208, and region mask (RgnMask) logic 212. In some embodiments, one or more of the components may be included in a refresh control circuit, such as refresh control circuit 116.

The MUX 206 may receive a row address RA[MSB:0], a refresh address RXADD (e.g., CBR address), and a region code ReCd. The row address RA may be provided by an address decoder, such as address decoder 104. The refresh address RXADD may be provided by CBR counter 202. As used herein, MSB refers to “most significant bit.” Further, as used herein, MSB refers to the MSB of the row address RA. Thus, in the example shown in FIG. 2, the refresh address includes [MSB-2:0], indicating RXADD is compressed by two bits or the two MSB of the RA are truncated. Thus, when RA represents one word line, RXADD may represent four word lines. However, other address compression schemes may be used in other examples.

The region code ReCd may be provided by fuse latches 204. The fuse latches 204 may be programmed based on values stored in fuses of a fuse array, such as fuse array 128. However, in other embodiments, the fuse latches 204 may be omitted, and ReCd may be provided directly from fuses of the fuse array. In the example shown in FIG. 2, the region code ReCd includes two bits [MSB:MSB-1]. This may allow masking in one quadrant of each memory bank in some applications. However, a different number of bits or different ones of the bits may be used in other examples, which may allow different regions of the memory banks to be masked.

The MUX 206 may receive a refresh signal AREF that determines the output of MUX 206. The MUX 206 may provide the output to multiple banks of the memory array (e.g., memory banks of memory array 118). When AREF is inactive (e.g., no refresh operation), the MUX 206 may pass the row address RA to redundancy circuitry 208 for analysis during access operations. The redundancy circuitry 208 may include one or more redundancy decoders 210. The redundancy decoders 210 may analyze the row address RA to determine if the row address RA matches any addresses corresponding to word lines that have been repaired. The redundancy circuitry 208 may include logic circuits (not shown) to OR the matches and output the result OR_Match. If a match is found, the appropriate redundant row in a redundant region of the memory array may be accessed instead of the defective row. If no match is found, the row in the main portion of the memory array indicated by the row address RA is accessed.

When AREF is active (e.g., a refresh operation occurs), the MUX 206 may output RXADD and ReCd as the row address RA. In the example shown in FIG. 2, ReCd may be [MSB:MSB-1] of RA[MSB:0], and RXADD may be [MSB-2:0] of RA[MSB:0]. However, RA[MSB:0] output by the MUX 206 during refresh operations may be made of a different combination of RXADD and ReCd. For example, RXADD may be compressed by more or fewer bits and/or different bits of the RA may be compressed to generate RXADD. Similarly, ReCd may be more or fewer bits and/or provide different bits of the RA.

The redundancy circuitry 208 may be activated during the refresh operation. The redundancy decoders 210 may analyze the row address RA (which during the refresh operation is ReCd+RXADD) to determine if the row address RA matches any addresses corresponding to word lines that have been repaired. The redundancy circuitry 208 may include logic circuits (not shown) to OR the matches and output the result OR_Match.

Region mask logic 212 may receive the result OR_Match from the redundancy circuitry 208. It may further receive RA[MSB:MSB-1] from the row address RA output from the MUX 206, which is the region code ReCd. The region mask logic 212 includes one or more circuits that generates a refresh region mask signal RefRgnMask based, at least in part, on OR_Match and RA[MSB:MSB-1]. If the region mask signal is active, the RXADD may be masked from refreshing. Thus, an active RefRgnMask signal may correspond to an active refresh masking Ref_Mask signal as shown in FIG. 1. In the example shown in FIG. 2, the RefRgnMask signal is four bits [3:0]. However, the width may be different in other examples and is based, at least in part, on the size of the selected region. The RefRgnMask may be provided to a row decoder, such as row decoder 108. Optionally, the region mask logic 212 may receive a refresh test signal RTEST which may disable the region mask logic 212 for certain operations, such as refreshing redundant row area in refresh cycle and/or testing of the memory device 200.

The CBR counter 202, fuse latches 204, and MUX 206 may be shared by multiple memory banks. In some embodiments, there may be separate region mask logic 212 for each memory bank. Similarly, some or all of the redundancy circuitry 208 may be separate for each memory bank. In some embodiments, components shared by multiple memory banks may be located in a peripheral region and components provided for each bank may be included in a bank logic region. However, the location of various components may be different depending on the layout.

In the example shown in FIG. 2, the selected region corresponds to a same quadrant of each memory bank. The refresh masking circuitry will mask the addresses of all of the repaired word lines in the selected quadrant (e.g., prevent refreshing of the repaired word lines). Repaired word lines in other quadrants will not be masked (e.g., will be refreshed). In other examples, the region may correspond to another segment of the memory banks rather than a quadrant.

Optionally, memory device 200 may further include refresh masking logic 214 for individual memory banks. The details of refresh masking logic 214 are provided in previously cited U.S. Patent 11,670,356. In these embodiments, the memory device 200 may include an OR logic circuit 216, and the RefRgnMask may be based on the OR of the output of the region mask logic 212 and the output of the refresh masking logic 214. This may allow masking of repaired rows in the memory bank that are outside the selected region(s) indicated by the region code ReCd.

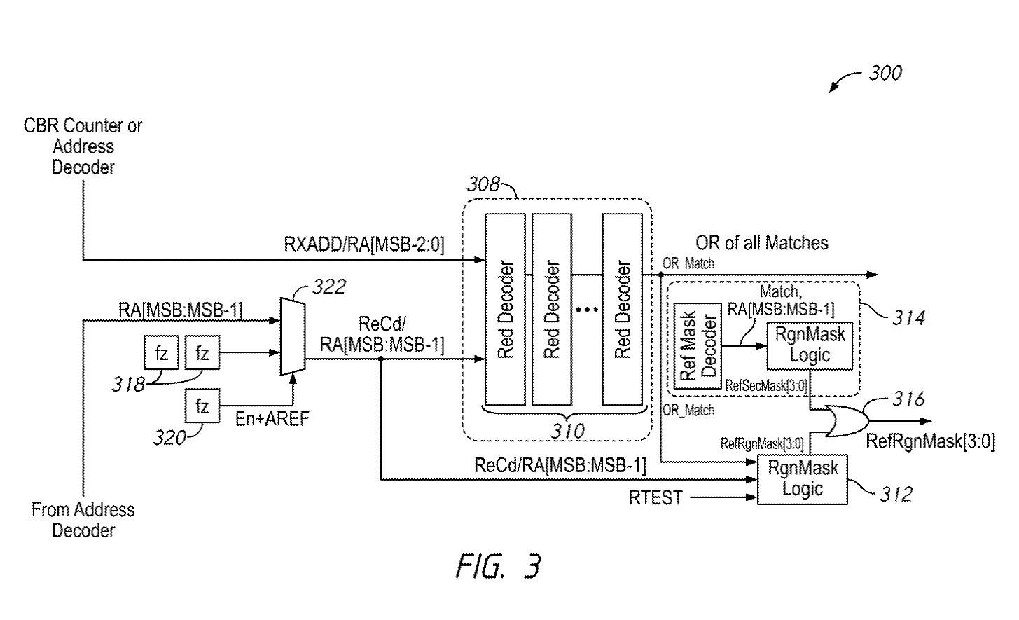

FIG. 3 is a block diagram of at least a portion of a memory device according to at least one embodiment of the disclosure. The memory device 300 may be included in memory device 100 in some embodiments. The memory device 300 may include a fuse latches 318 and 320, multiplexer (MUX) 322, redundancy circuitry 308, and region mask (RgnMask) logic 312. In some embodiments, one or more of the components may be included in a bank logic region of a memory bank. For the sake of brevity, features and operations similar to those already described with respect to FIG. 2 will not be repeated again with respect to FIG. 3.

The refresh masking circuitry illustrated in FIG. 2 shared the fuse latches 204 amongst all of the memory banks. Thus, the repaired rows in same region in each memory bank were masked. However, in some instances, different banks may have different regions with defective word lines. Accordingly, it may be desirable to mask different regions of some or all of the banks.

In the embodiment shown in FIG. 3, the region code ReCd for a specific bank may be stored in fuse latches 318. Each individual bank may include their own set of fuse latches 318. The fuse latches 318 may be programmed based on values stored in fuses of a fuse array, such as fuse array 128. However, in other embodiments, the fuse latches 318 may be omitted, and ReCd may be provided directly from fuses of the fuse array.

The MUX 322 may receive the region code ReCd from fuse latches 318 as well as a portion of a row address RA. The row address RA may be provided by an address decoder. In the example shown, the portion of the row address includes [MSB:MSB-1], but other portions may be included in other examples.

Fuse latch 320 may be programmed to control the MUX 322. When fuse latch 320 is programmed to provide an active enable En signal to the MUX 322, the MUX 322 outputs the region code ReCd from fuse latches 318 when an active refresh signal AREF is received. During access operations (e.g., AREF is not active), the MUX 322 may output the portion of the row address RA[MSB:MSB-1]. When fuse latch 320 is programmed to provide an inactive enable signal En with an active AREF signal, the MUX 322 may output the portion of the row address during access operations and may not provide an output during refresh operations. In other embodiments, fuse latch 318 information may be provided during refresh operations.

During access operations, the redundancy circuitry 308 receives a portion of the row address RA from an address decoder and the remaining portion of the row address RA from the MUX 322. During refresh operations, the redundancy circuitry 308 receives a refresh address RXADD from a CBR counter and the region code ReCd from MUX 322. The region mask logic 312 may provide a refresh region mask signal RefRngMask based on the region code ReCd and the output of the redundancy circuitry 308 in a similar manner as described with reference to FIG. 2. As in FIG. 2, the memory device 300 may optionally include refresh masking logic 314 and OR logic circuit 316.

The embodiment shown in FIG. 3 may utilize separate channels for the refresh address RXADD and region code ReCD as well as individual fuse latches for each bank (and/or additional fuses in the fuse array). This may require more components and/or layout space compared to the embodiment shown in FIG. 2. However, the advantages of being able designate a different region to mask for each bank may outweigh the disadvantages of additional components and/or layout space in some applications.

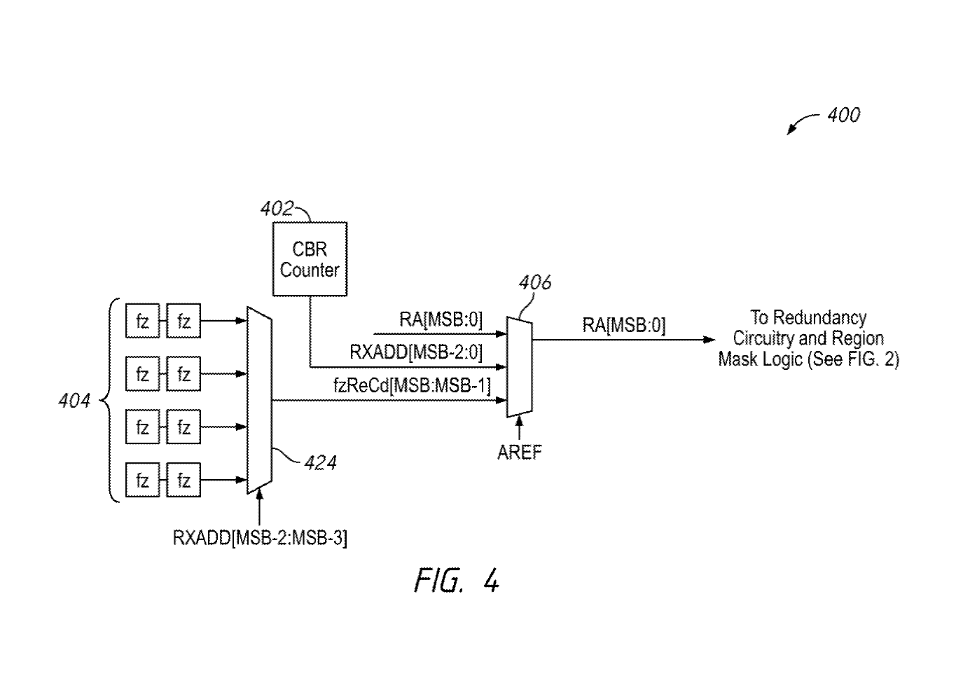

FIG. 4 is a block diagram of at least a portion of a memory device according to at least one embodiment of the disclosure. The memory device 400 may be included in memory device 100 in some embodiments. The memory device 400 may include a CBR counter 402, fuse latches 404, multiplexer (MUX) 406, and MUX 424. In some embodiments, one or more of the components may be included in a refresh control circuit, such as refresh control circuit 116. For the sake of brevity, features and operations similar to those already described with respect to FIG. 2 will not be repeated again with respect to FIG. 4.

Similar to FIG. 2, the MUX 406 may receive a row address RA[MSB:0], a refresh address RXADD (e.g., CBR address), and a region code ReCd. The row address RA may be provided by an address decoder, such as address decoder 104. The refresh address RXADD may be provided by CBR counter 402. However, in contrast to FIG. 2, the MUX 406 may receive one of several stored region codes ReCd from MUX 424.

The region codes ReCd may be stored in fuse latches 404. The fuse latches 404 may be programmed based on values stored in fuses of a fuse array, such as fuse array 128. However, in other embodiments, the fuse latches 404 may be omitted, and the region codes ReCd may be provided directly from fuses of the fuse array. In the example shown in FIG. 4, there are eight fuse latches 404, storing four region codes (e.g., four sets of two fuse latches). However, in other examples, more or fewer region codes may be stored.

The MUX 424 may receive a portion of the refresh address RXADD. In the example in FIG. 4, the MUX 424 receives [MSB-2:MSB-3]. However, in other examples, different portions of the refresh address RXADD may be used. Further, a different number of bits may be received based on the number of region codes stored in other examples. The MUX 424 may output the region code ReCd based on the received portion of RXADD.

Similar to MUX 206, the MUX 406 may receive a refresh signal AREF that determines the output of MUX 406. The MUX 406 may provide the output to multiple banks of the memory array (e.g., memory banks of memory array 118). The output may be provided to redundancy circuitry and region mask logic as shown in FIG. 2.

The embodiment shown in FIG. 4 may allow for regions masked in refresh operations to be divided into subregions. In the example shown, each region may be divided into four subregions. Other numbers of subregions may be used in other examples. The embodiment shown in FIG. 4 may be beneficial in certain applications such as when there are multiple large defects (e.g., multiple adjacent/nearby word lines) in different regions. The multiple selectable region codes allow for masking off repaired rows from firing in the different regions. Because the fuse latches 404 are shared amongst the banks, the increase in layout area compared to the embodiment shown in FIG. 4 may be acceptable.

In some embodiments, the feature of multiple region codes may be applied to the embodiment shown in FIG. 3. In this embodiment, instead of only one set of fuse latches 318, additional fuse latches are provided to store region codes (e.g., eight fuse latches as shown in FIG. 4), and an additional MUX is provided that receives a portion of RXADD. The region code ReCd indicated by the portion of the RXADD is provided from the additional MUX to the MUX 322. This embodiment may permit each bank to have different divisions of sub regions for refresh masking. However, this embodiment includes additional fuse latches and a multiplexer for each bank and/or additional fuses in the fuse array for each bank. Accordingly, the increase in layout size and/or number of components may be significant compared to the embodiments shown in FIGS. 2 and 4.

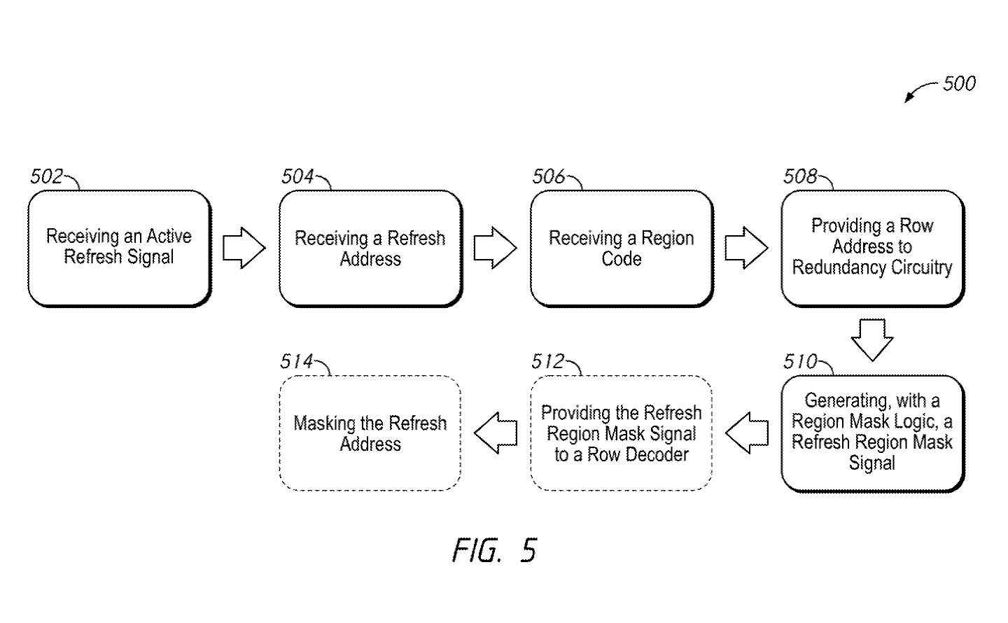

FIG. 5 is a flow chart of a method according to at least one embodiment of the disclosure. The method 500 may, in some embodiments, be executed by one or more of the memory devices described in FIGS. 1-4.

At block 502, “receiving an active refresh signal” may be performed. In some embodiments, the active refresh signal may be provided by a command decoder, such as command decoder 106. At block 504, “receiving a refresh address” may be performed. In some embodiments, the refresh address may be provided by a refresh counter such as CBR counter 202 and/or CBR counter 402.

At block 506 “receiving a region code” may be performed. In some embodiments, the region code may be provided by fuse latches such as fuse latches 204, fuse latches 318, and/or fuse latches 404. The fuse latches may be programmed with the region code during a broadcast operation where the region code stored in fuses is provided and stored in the fuse latches. In some embodiments, the region code may be provided directly from fuses of a fuse array such as fuse array 128. In some embodiments, the region code may be selected from multiple region codes, for example, as shown in FIG. 4. In some embodiments, which region code is provided is based, at least in part, on a portion of the refresh address.

Responsive at least in part to the active refresh signal, at block 508 “providing a row address to redundancy circuitry” may be performed. In some embodiments, the row address comprises the refresh address and the region code. In some embodiments, the region code makes up at least one most significant bit (MSB) of the row address and the refresh address makes up remaining bits of the row address. In some examples, the region code makes up the two MSBs of the row address. In some embodiments, the refresh address and the region code may be provided on a same channel as shown in FIGS. 2 and 4. In other embodiments, the region code and refresh address may be provided separately as shown in FIG. 3. In some embodiments, the row address may be provided by a multiplexer as shown in FIGS. 2 and 4. In some embodiments, the refresh address is provided from a refresh counter and the region code is provided from a multiplexer as shown in FIG. 3.

At block 510 “generating, with a region mask logic, a refresh region mask signal.” In some embodiments, the refresh mask signal is based, at least in part, on an output of the redundancy circuitry and the region code.

In some embodiments, method 500 may further include block 512 where “providing the refresh region mask signal to a row decoder” may be performed and block 514 where “masking the refresh address” may be performed. Masking the refresh address may prevent refreshing of at least one word line associated with the refresh address.

The systems, methods, and apparatuses disclosed herein may allow masking of refresh addresses corresponding to defective word lines in one or more regions of a memory array. Masking the refresh addresses may prevent refreshing of the defective word lines. Preventing refreshing of certain defective word lines may reduce the risk of corrupting data, damaging the memory device, and/or harming memory device performance.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory array;
a plurality of fuses configured to store a region code, wherein the region code indicates a region of the memory array;
a multiplexer configured to provide a refresh address and the region code as a row address during a refresh operation;
redundancy circuitry configured to determine whether a word line indicated by the row address has been repaired by a redundant word line and provide an output; and
a region mask logic configured to generate a region mask signal based on the region code and the output, wherein the region mask signal masks the refresh address when the output indicates the word line has been repaired.

2. The apparatus of claim 1, wherein the memory array comprises a plurality of memory banks and the multiplexer provides the refresh address and the region code to the plurality of memory banks.

3. The apparatus of claim 1, further comprising a plurality of fuse latches, wherein the plurality of fuse latches are configured to receive the region code from the plurality of fuse latches and provide the region code to the multiplexer.

4. The apparatus of claim 1, wherein the plurality of fuses are configured to store a plurality of region codes, and the apparatus further comprises a second multiplexer configured to provide the region code from the plurality of region codes.

5. The apparatus of claim 4, wherein the region code is selected from the plurality of region codes based on a portion of the refresh address.

6. The apparatus of claim 1, further comprising a row decoder configured to receive the region mask signal.

7. An apparatus comprising:
a refresh counter configured to provide a refresh address;
a memory array comprising a plurality of memory banks;
a plurality of sets of fuse latches associated with corresponding ones of the plurality of memory banks, wherein each of the plurality of sets of fuse latches are configured to store a region code, wherein the region code indicates a region of a memory bank of the plurality of memory banks;
a plurality of multiplexers associated with corresponding ones of the plurality of sets of fuse latches and configured to provide the region code during a refresh operation;
a plurality of redundancy circuitry associated with corresponding ones of the plurality of memory banks configured to determine whether a word line indicated by the refresh address and the region code has been repaired by a redundant word line and provide an output; and
a plurality of region mask logic associated with corresponding ones of the plurality of memory banks configured to generate a region mask signal based on the region code and the output, wherein the region mask signal masks the refresh address when the output indicates the word line has been repaired.

8. The apparatus of claim 7, further comprising a plurality of fuse latches configured to be programmed to enable corresponding ones of the plurality of multiplexers.

9. The apparatus of claim 7, wherein the plurality of sets of fuse latches are configured to store a plurality of region codes, and the apparatus further comprises a second plurality of multiplexers configured to provide the region code from the plurality of region codes.

10. The apparatus of claim 9, wherein the region code is selected from the plurality of region codes based, at least in part, on a portion of the refresh address.

11. A method comprising:
receiving an active refresh signal;
receiving a refresh address;
receiving a region code;
responsive at least in part to the active refresh signal, providing a row address to redundancy circuitry, wherein the row address comprises the refresh address and the region code; and
generating, with a region mask logic, a refresh region mask signal based, at least in part, on an output of the redundancy circuitry and the region code.

12. The method of claim 11, further comprising:
providing the refresh region mask signal to a row decoder; and
masking the refresh address, wherein masking the refresh address prevents refreshing of at least one word line associated with the refresh address.

13. The method of claim 11, wherein the region code comprises at least one most significant bit (MSB) of the row address and the refresh address comprises remaining bits of the row address.

14. The method of claim 13, wherein the region code comprises two of the MSBs.

15. The method of claim 11, further comprising performing a broadcast operation, wherein the broadcast operation comprises:
providing the region code stored in a plurality of fuses to a plurality of fuse latches; and
storing the region code in the plurality of fuse latches.

16. The method of claim 11, wherein the region code corresponds to a portion of a memory array.

17. The method of claim 11, wherein the active refresh signal, the refresh address, and the region code are received by a multiplexer, and the multiplexer provides the row address to the redundancy circuitry.

18. The method of claim 11, further comprising, selecting the region code from a plurality of region codes.

19. The method of claim 18, wherein the region code is selected based on at least a portion of the refresh address.

20. The method of claim 11, wherein the region code is provided to redundancy circuitry of a plurality of memory banks.
